(19) United States
(12) Patent Application Publication
(10) Pub. No.: US 2013/0307145 A1
(43) Pub. Date: Nov. 21, 2013

(54) SEMICONDUCTOR PACKAGE AND METHOD OF FABRICATING THE SAME

(71) Applicant: FAIRCHILD KOREA SEMICONDUCTOR LTD., (unknown)

(72) Inventors: Yoon-jae CHUNG, Goyang (KR); Yong LIU, Scarborough, ME (US); Seung-won IM, Bucheon (KR); Byoung-ok LEE, Bucheon (KR); Taek-keun LEE, Bucheon (KR); Joon-seo SON, Seoul (KR); O-seob JEON, Seoul (KR)

(73) Assignee: FAIRCHILD KOREA SEMICONDUCTOR LTD., Bucheon (KR)

(21) Appl. No.: 13/780,184

(22) Filed: Feb. 28, 2013

(30) Foreign Application Priority Data
May 21, 2012 (KR) 10-2012-0053779

(51) Int. Cl. H01L 23/498; H01L 21/56

(52) U.S. Cl. CPC H01L 23/49811; H01L 21/56
USPC 257/737; 438/124

(57) ABSTRACT

A semiconductor package including a package substrate; a semiconductor chip on the package substrate; a first via contact on the package substrate; a second via contact on the semiconductor chip; a metal wiring, which is arranged on the first via contact and the second via contact and interconnects the first via contact and the second via contact; a first encapsulating material which is arranged between the metal wiring and the package substrate and encapsulates the semiconductor chip, the first via contact, and the second via contact; and a second encapsulating material which encapsulates the first encapsulating material and the metal wiring.

### CROSS-REFERENCE TO RELATED PATENT APPLICATION

This application claims the benefit of Korean Patent Application No. 10-2012-0053779, filed on May 21, 2012, in the Korean Intellectual Property Office, the disclosure of which is incorporated herein in its entirety by reference.

### BACKGROUND OF THE INVENTION

1. Field of the Invention

The present invention relates to a semiconductor package and a method of fabricating the same, and more particularly, to a semiconductor package with improved electric properties and a method of fabricating the same.

2. Description of the Related Art

Generally, a semiconductor package is fabricated by mounting at least one semiconductor chip on a package substrate, electrically connecting the semiconductor chip and the package substrate to each other via a wire or the like, and encapsulating the semiconductor chip with an encapsulating material.

In addition, along with recent increases in speed, capacity, and integration of electronic devices, the demands for inexpensive, small, and lightweight power devices applied to automobiles, industrial machines, and consumer electronics have increased. Furthermore, semiconductor packages with low heat radiation and high reliability are in demand.

### SUMMARY OF THE INVENTION

The present invention provides a semiconductor package with improved electric properties and longer lifespan and a method of fabricating the same

According to an aspect of the present invention, there is provided a semiconductor package including a package substrate; a semiconductor chip on the package substrate; a first via contact on the package substrate; a second via contact on the semiconductor chip; a metal wiring, which is arranged on the first via contact and the second via contact and interconnects the first via contact and the second via contact; a first encapsulating material which is arranged between the metal wiring and the package substrate and encapsulates the semiconductor chip, the first via contact, and the second via contact; and a second encapsulating material which encapsulates the first encapsulating material and the metal wiring.

The semiconductor package may further include a shim arranged between the first via contact and the package substrate.

The cross-section of the first via contact may have a reverse-trapezoidal shape, and the cross-section of the shim may have a rectangular shape.

The first via contact may contact the shim.

The semiconductor package may further include a bump arranged between the semiconductor chip and the second via contact. The top surface of the shim may be aligned with a top surface of the bump.

The semiconductor chip may include a pad; a passivation film covering a top surface of the semiconductor chip to expose at least a portion of the pad; and a bump which contacts the portion of the pad exposed by the passivation film.

The second via contact may contact the bump.

A bottom surface of the metal wiring may contact the first encapsulating material, and a top surface of the metal wiring may contact the second encapsulating material.

According to another aspect of the present invention, there is provided a method of fabricating a semiconductor package, the method including fixing a semiconductor chip onto a package substrate; laminating a semi-hardened first encapsulating material of which a top surface is coated with a conductive film onto the package substrate and the semiconductor chip; forming a first via contact that connects to the package substrate and a second via contact that connects to the semiconductor chip by partially removing the conductive film and the first encapsulating material; forming a metal wiring interconnecting the first via contact and the second via contact by patterning the conductive film; and forming a second encapsulating material which encapsulates the first encapsulating material and the metal wiring.

The lamination may be performed by using a resin-coated Cu foil (RCC).

The method may further include, before the laminating of the semi-hardened first encapsulation material onto the package substrate and the semiconductor chip, fixing a shim to the package substrate.

The semiconductor chip may include a pad and a bump arranged on the pad, and a top surface of the shim may be aligned with a top surface of the bump.

The forming of the first via contact and the second via contact may include forming a first opening exposing the top surface of the shim and a first opening exposing the top surface of the bump by partially removing the conductive film and the first encapsulating material; and forming the first via contact and the second via contact by filling the first opening and the second opening with metals.

The first opening and the second opening may be formed using laser-drilling.

The semiconductor chip may be fixed onto the package substrate via at least one process including soldering, silver (Ag) sintering, and diffusion soldering.

According to another aspect of the present invention, there is provided a method of forming a semiconductor package, the method including fixing a first semiconductor chip and a second semiconductor chip onto a master card; forming a first encapsulating material and a conductive film on the master card, the first semiconductor chip, and the second semiconductor chip; forming a first via contact that connects to the master card, a second via contact that connects to the first semiconductor chip, a third via contact that connects to the master card, and a fourth via contact that connects to the second semiconductor chip by partially removing the conductive film and the first encapsulating material; forming a first metal wiring interconnecting the first via contact and the second via contact and a second metal wiring interconnecting the third via contact and the fourth via contact by patterning the conductive film; and splitting the master card into a first package substrate and a second package substrate.

The forming of the first encapsulating material and the conductive film may include laminating the semi-hardened first encapsulating material of which a top surface is coated with the conductive film onto the master card, the first semiconductor chip, and the second semiconductor chip.

The first semiconductor chip, the first via contact, the second via contact, a first portion of the first encapsulating material, and the first metal wiring may be arranged on the first package substrate, and the second semiconductor chip, the second via contact, the second via contact, a second portion of the first encapsulating material, and the second metal wiring may be arranged on the second package substrate.

The method may further include encapsulating the first portion of the first encapsulating material with a second encapsulating material.

The method may further include, before the encapsulating of the first portion of the first encapsulating material with the second encapsulating material, connecting the first package substrate to an external terminal.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic sectional view of a semiconductor package according to an embodiment of the present invention;

FIGS. 2 and 3 are schematic sectional views of semiconductor packages according to embodiments of the present invention, respectively;

FIG. 4 is a diagram showing region A of FIG. 3 in closer detail; i.e., a detailed view of a structure on which a bump is formed;

FIG. 5 is a schematic sectional view of a semiconductor package according to another embodiment of the present invention;

FIGS. 6 and 7 are perspective views for comparing a semiconductor package employing wire bonding in the related art to a semiconductor package according to an embodiment of the present invention, respectively;

FIGS. 8 through 14 are schematic sectional views sequentially showing a method of fabricating a semiconductor package, according to an embodiment of the present invention; and

FIGS. 15 and 16 are schematic sectional views showing methods of fabricating semiconductor packages, according to other embodiments of the present invention.

### DETAILED DESCRIPTION OF THE INVENTION

Hereinafter, the present invention will be described in detail by explaining preferred embodiments of the invention with reference to the attached drawings.

The invention may, however, be embodied in many different forms and should not be construed as being limited to the embodiments set forth herein; rather, these embodiments are provided so that this disclosure will be thorough and complete, and will fully convey the concept of the invention to those skilled in the art.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added. As used herein, the term “and/or” includes any and all combinations of one or more of the associated listed items.

It will be understood that although the terms first and second are used herein to describe various elements, these elements should not be limited by these terms. These terms are only used to distinguish one element from another element. Thus, a first element discussed below could be termed a second element, and similarly, a second element may be termed a first element without departing from the teachings of this disclosure.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

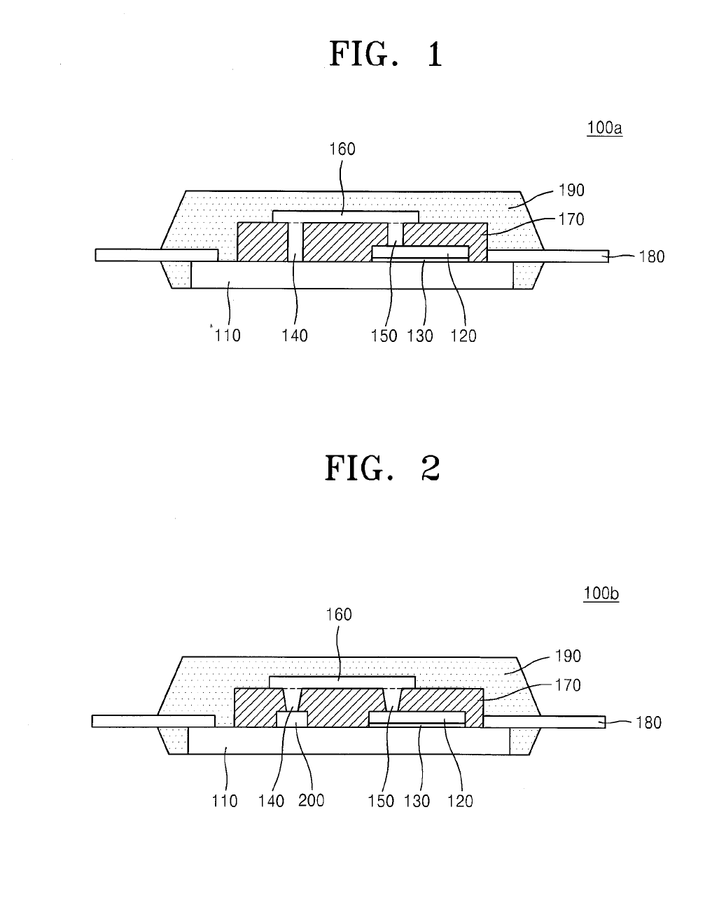

FIG. 1 is a schematic sectional view of a semiconductor package 100a according to an embodiment of the present invention.

Referring to FIG. 1, the semiconductor package 100a may include a package substrate 110, a semiconductor chip 120, a fixing unit 130, a first via contact 140, a second via contact 150, a metal wiring 160, a first encapsulating material 170, an external terminal 180, and a second encapsulating material 190.

The package substrate 110 is a printed circuit board (PCB) and may have a single layer structure or a multilayer structure having wiring patterns therein, for example. In other words, the package substrate 110 may be a single rigid substrate, may be formed by adhering a plurality of rigid substrates to each other, or may be formed by adhering a thin flexible PCB to a rigid flat panel. Each of the plurality of rigid substrates may include a wiring pattern and a connecting pad. Furthermore, the package substrate 110 may be a low temperature co-fired ceramic (LTCC) substrate. In the LTCC substrate, a plurality of ceramic layers may be stacked, and wiring patterns may be formed on each of the ceramic layers.

For example, the package substrate 110 may be a direct bonded copper (DBC) substrate in which copper layers are attached to two opposite surfaces of an insulation layer. The insulation layer may contain epoxy resin, polyimide resin, bismalemide triazine (BT) resin, flame retardant 4 (FR-4), FR-5, ceramic, silicon, or glass. However, the present invention is not limited thereto.

The semiconductor chip 120 may be fixed on the package substrate 110 via the fixing unit 130. For example, as the fixing unit 130 formed of a conductive material is interposed between the semiconductor chip 120 and the package substrate 110, the semiconductor chip 120 may be fixed on the package substrate 110 (in this case, the bottom surface of the semiconductor chip 120 may include a conductive region). To form the fixing unit 130, a process such as soldering, silver (Ag) sintering, or diffusion soldering may be performed. According to another embodiment of the present invention, the fixing unit 130 may be an adhesive tape. In this case, the adhesive tape may include glass tape, silicon tape, Teflon tape, stainless foil tape, ceramic tape, etc. Furthermore, the adhesive tape may contain aluminium oxide, aluminium nitride, silicon oxide, or beryllium oxide.

The first via contact 140 may be arranged on the package substrate 110. The first via contact 140 may either directly contact the package substrate 110 or be electrically connected to the package substrate 110 via a shim (not shown). Side surfaces of the first via contact 140 may be surrounded by the first encapsulating material 170, and the top surface of the first via contact 140 may contact the metal wiring 160.

The second via contact 150 may be arranged on the semiconductor chip 120. The second via contact 150 may either directly contact the semiconductor chip 120 or be electrically connected to the semiconductor chip 120 via a bump (not shown). Side surfaces of the second via contact 150 may be surrounded by the first encapsulating material 170, and the top surface of the second via contact 150 may contact the metal wiring 160.

The metal wiring 160 may be arranged on the first via contact 140 and the second via contact 150. For example, the metal wiring 160 may be arranged to interconnect the first via contact 140 and the second via contact 150. The bottom surface of the metal wiring 160 may contact the first encapsulating material 170 or may contact the first via contact 140 and the second via contact 150. In addition, side surfaces and the top surface of the metal wiring 160 may contact the second encapsulating material 190.

The first encapsulating material 170 may be arranged between the metal wiring 160 and the package substrate 110 and may encapsulate the semiconductor chip 120, the first via contact 140, and the second via contact 150. The first encapsulating material 170 may contain a material that is rigid at room temperature and is flexible at a high temperature. For example, the first encapsulating material 170 may contain resin. Furthermore, the first encapsulating material 170 may contain polycarbonate, polyimide, polyester, polyamide, or the like.

The second encapsulating material 190 may encapsulate the first encapsulating material 170, the external terminal 180, and the metal wiring 160. The second encapsulating material 190 may contain epoxy. Furthermore, the second encapsulating material 190 may or may not be formed of a same material as the first encapsulating material 170. The external terminal 180 may be fixed to the package substrate 110 and may be electrically connected to the package substrate 110. A side surface of the external terminal 180 may be exposed, whereas the other side surfaces of the external terminal 180 may contact the first encapsulating material 170 or the second encapsulating material 190.

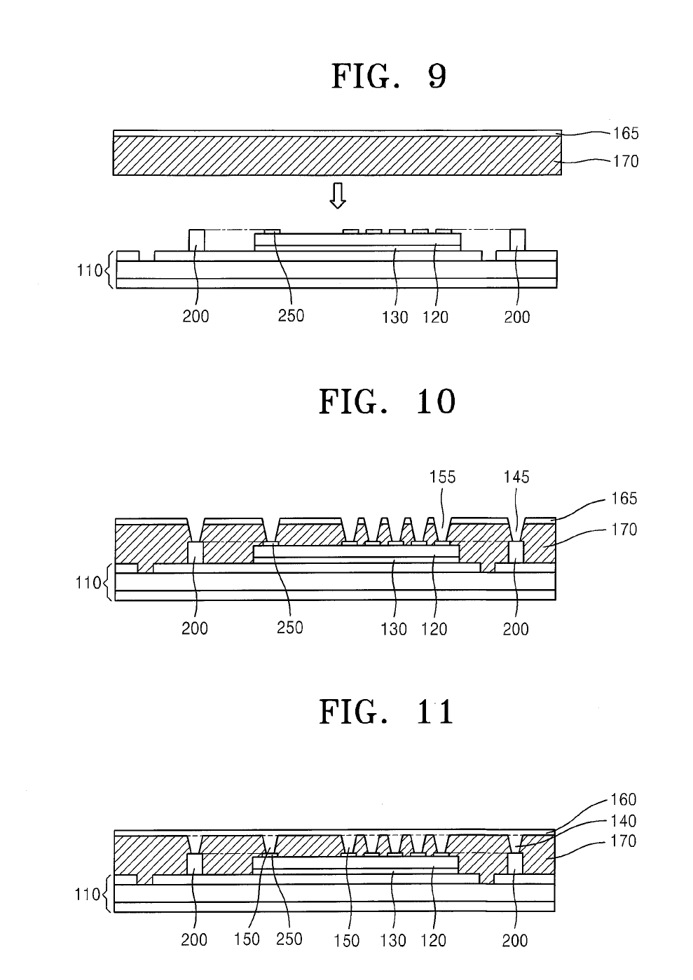

It is noted that the electrical connection between the semiconductor chip 120 and the package substrate 110 is established via the first via contact 140, the metal wiring 160, and the second via contact 150. A semiconductor package 100a with an electric connection according to an embodiment of the present invention may have longer lifespan and superior electric properties than a semiconductor package 100a in which an electric connection is made via wire bonding in the related art. The technical advantages of the present invention will be described below in detail with reference to FIGS. 6 and 7.

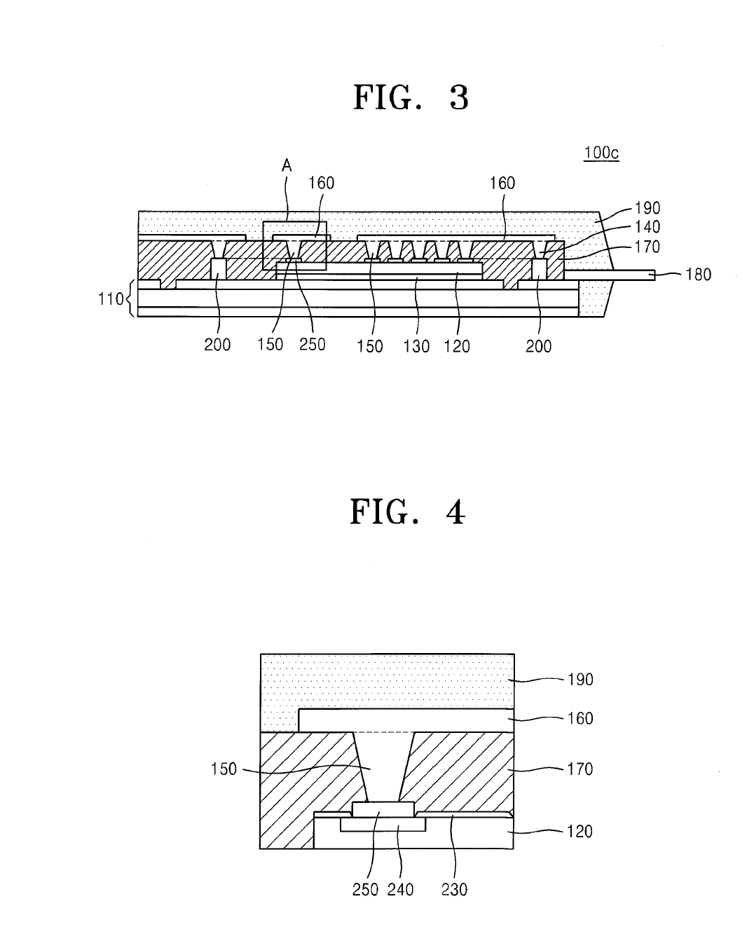

FIGS. 2 and 3 are schematic sectional views of semiconductor packages 100b and 100c according to embodiments of the present invention, respectively. The semiconductor packages 100b and 100c may be modifications of the semiconductor package 100a of FIG. 1. Thus, repeated descriptions of the same elements are omitted.

Referring to FIG. 2, the semiconductor package 100b may further include a shim 200 between the package substrate 110 and the first via contact 140. The shim 200 is a cuboidal or cylindrical conductor and may contain a conductive material, e.g., copper. The bottom surface of the shim 200 may contact the package substrate 110, and side surfaces of the shim 200 may contact the first encapsulating material 170. The top surface of the shim 200 may contact the bottom surface of the first via contact 140. In detail, a portion of the top surface of the shim 200 may contact the first via contact 140, whereas the other portion of the top surface of the shim 200 may contact the first encapsulating material 170.

According to an embodiment of the present invention, the first via contact 140 may have a reverse trapezoid cross-sectional shape, whereas the shim 200 may have a rectangular cross-sectional shape. The first via contact 140 and the shim 200 may directly contact each other. In this case, a conductor having a shape equivalent to a combination of a reverse trapezoid and a rectangle may be arranged between the metal wiring 160 and the package substrate 110.

Although FIG. 2 shows that a conductor having a shape equivalent to a combination of a reverse trapezoid and a rectangle is arranged between the metal wiring 160 and the package substrate 110, the present invention is not limited thereto. For example, the first via contact 140 may have a rectangular cross-section with the same width as that of the shim 200 (in this case, a result similar to that shown in FIG. 1 may be obtained), or the first via contact 140 may have a rectangular cross-section with a width smaller than that of the shim 200. Furthermore, the cross-sectional shape of the shim 200 may also be trapezoidal or reversed-trapezoidal.

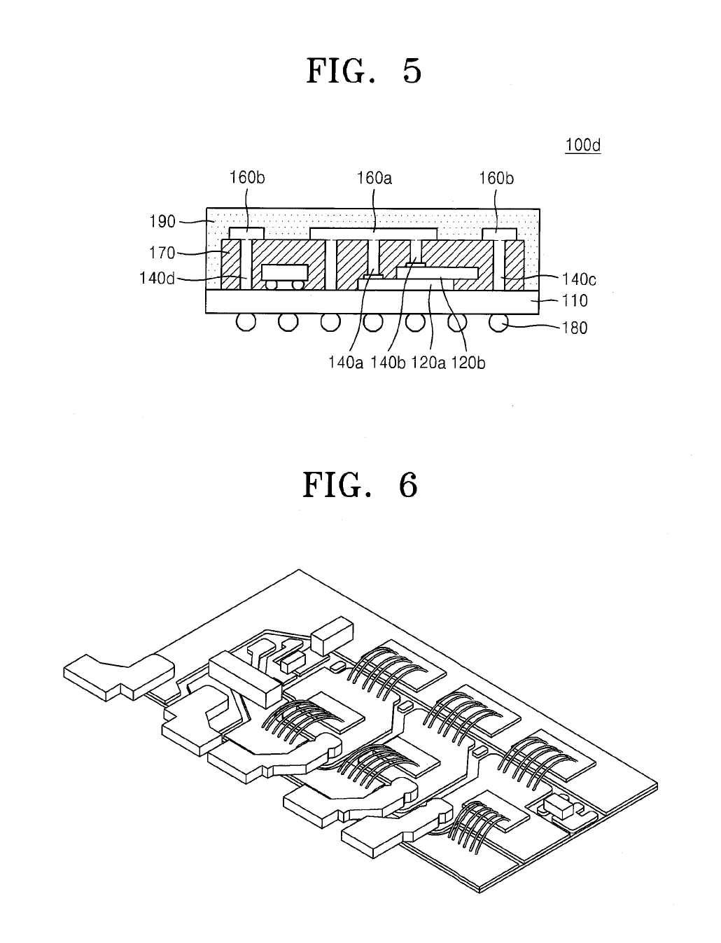

Referring to FIG. 3, the package substrate 110 of the semiconductor package 100c may have a structure in which copper layers are attached to two opposite surfaces of an insulation layer, that is, a DBC substrate. Furthermore, the semiconductor package 100c may further include a bump 250 arranged between the semiconductor chip 120 and the second via contact 150. The bump 250 may be a conductor that is attached onto a pad 240 of the semiconductor chip 120 during a wafer forming process, for example (see FIG. 4). FIG. 4 is a diagram showing region A of FIG. 3 in closer detail; i.e., a detailed view of a structure on which the bump 250 is formed.

Referring to FIG. 4, the semiconductor chip 120 may include the pad 240, a passivation layer 230, and the bump 250. The passivation layer 230 may cover the top surface of the semiconductor chip 120 (e.g., an active surface) and expose at least a portion of the pad 240, and the bump 250 may contact the portion of the pad 240, which is exposed by the passivation layer 230. The bottom surface of the bump 250 may contact the top surface of the semiconductor chip 120 (particularly, the pad 240), whereas the side surfaces of the bump 250 may contact the first encapsulating material 170. The top surface of the bump 250 may contact the bottom surface of the second via contact 150. In detail, a portion of the top surface of the bump 250 may contact the bottom surface of the second via contact 150, whereas the other portion of the top surface of the bump 250 may contact the first encapsulating material 170.

Referring back to FIG. 3, the top surface of the shim 200 may be aligned with the top surface of the bump 250 (indicated by a chain line in FIG. 3). In other words, the top surface of the shim 200 and the top surface of the bump 250 may be on the same plane. In detail, the shim 200 may have a height that is levelled with the top surface of the bump 250. Therefore, for example, the height of the shim 200 may be equal to a sum of heights of the fixing unit 130, the semiconductor chip 120, and the bump 250.

This feature contributes to smooth formation of the first via contact 140 and the second via contact 150. For example, since the shim 200 is formed at a height similar to that of the semiconductor chip 120 (or the bump 250), a balanced plating process for forming the first via contact 140 and the second via contact 150 may be performed.

Furthermore, since the bump 250 is provided on the semiconductor chip 120, the semiconductor chip 120 may be protected during formation of the first via contact 140 and the second via contact 150. For example, if openings are formed through laser-trilling to form the first via contact 140 and the second via contact 150, the bump 250 formed on the semiconductor chip 120 prevents damage to the semiconductor chip 120 by the laser-drilling.

Although FIGS. 1 through 3 only show that the semiconductor chip 120 and the package substrate 110 are connected via the first via contact 140, the metal wiring 160, and the second via contact 150, the present invention is not limited thereto. For example, a semiconductor chip may be connected to another semiconductor chip or a portion of a package substrate may be connected to another portion of the package substrate via a via contact, a metal wiring, and another via contact.

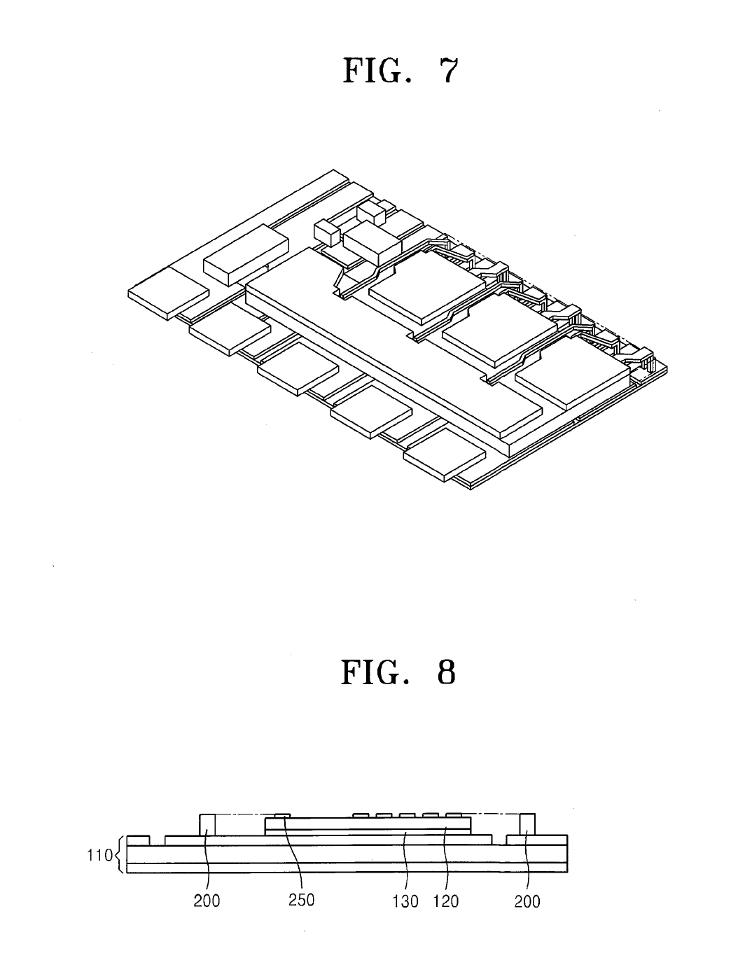

For example, as shown in FIG. 5, a first semiconductor chip 120a and a second semiconductor chip 120b may be connected to each other via a via contact 140a, a metal wiring 160a, and a via contact 140b (the first semiconductor chip 120a and the second semiconductor chip 120b may not be stacked on each other and may both be fixed onto the package substrate 110). Furthermore, a portion of the package substrate 110 may be connected to another portion of the package substrate 110 via a via contact 140c, a metal wiring 160b, and a via contact 140d.

FIGS. 6 and 7 are perspective views for comparing a semiconductor package employing wire bonding in the related art to a semiconductor package according to an embodiment of the present invention, respectively.

Referring to FIG. 6, in the semiconductor package in the related art, bonding wires are used to interconnect a semiconductor chip and a package substrate.

If the semiconductor chip and the package substrate are connected to each other via wire bonding, due to a long current path of the bonding wires, the resistance and inductance of the bonding wires increase. The increased resistance of the bonding wires causes power loss. Furthermore, due to the increased inductance, signal interference may occur. Furthermore, crosstalk may occur between the bonding wires.

Particularly, in a semiconductor package employing wire bonding, external shock to the semiconductor package is transmitted to wires, and thus, connections between wires and a package substrate or between wires and semiconductor chips may often crack. Therefore, the average lifespan of semiconductor packages is often reduced.

As shown in FIG. 7, in a semiconductor package according to an embodiment of the present invention, a semiconductor chip is connected to a package substrate via a via contact, a metal wiring, and a via contact. Therefore, the problem o defects due to a bonding wire process in the related art may be resolved. For example, the resistance of a current path may be reduced either by increasing the thickness of via contacts or by increasing the number of via contacts, and thus, power loss may be reduced. Furthermore, since a semiconductor chip is connected to a package substrate via a short metal wiring, inductance may also be reduced.

Table 1 shows results of simulations on the semiconductor packages of FIGS. 6 and 7, where the semiconductor package according to the present invention has improved properties as compared to the semiconductor package in the related art.

TABLE 1

| | With Bonding | Present Invention |
|---|---|---|
| Properties | Wire (FIG. 6) | (FIG. 7) |
| Size (e.g., DBC size) | 1x | 0.85x |
| Inductance | 1x | 0.68x |
| Resistance | 1x | 0.83x |
| Capacitance | 1x | 0.35x |

Table 1 shows that the semiconductor package according to the present invention has improved properties, including inductance and resistance (capacitance may also be reduced). Furthermore, although a spare space in a package substrate is needed for bonding wires in the related art, such a space is not needed in the present invention, and thus, the size of a semiconductor package according to the present invention may decrease.

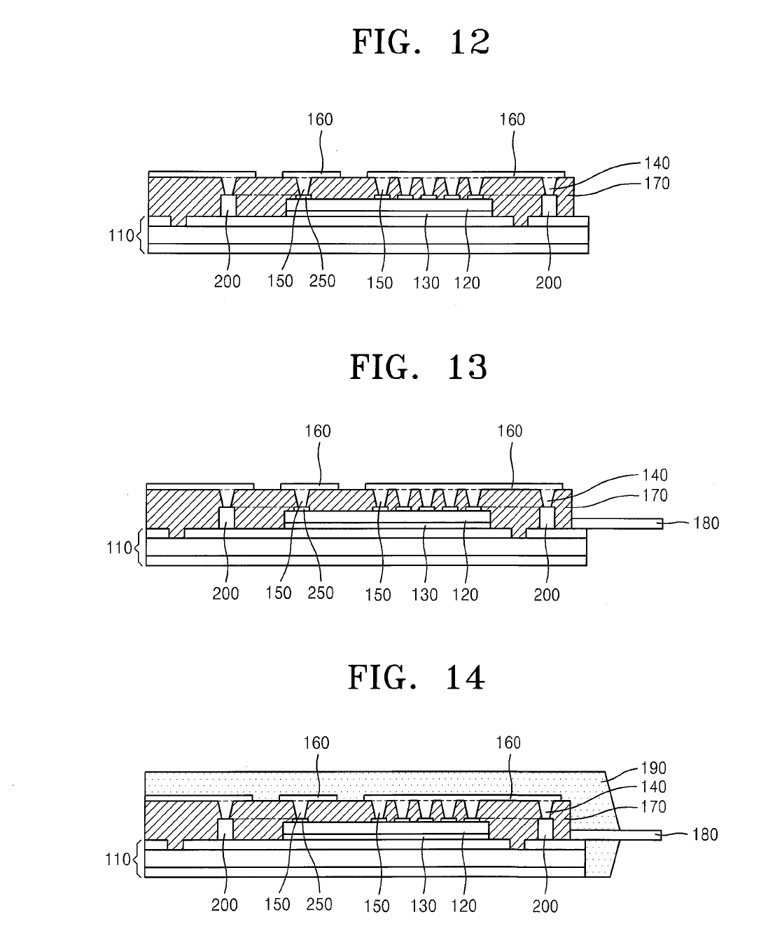

FIGS. 8 through 14 are schematic sectional views sequentially showing a method of fabricating a semiconductor package, according to an embodiment of the present invention.

Referring to FIG. 8, the semiconductor chip 120 and the shim 200 are fixed on the package substrate 110. To this end, the fixing unit 130 may be arranged between the semiconductor chip 120 and the package substrate 110. Selectively, the fixing unit 130 may also be arranged between the shim 200 and the package substrate 110. Since the package substrate 110 and the shim 200 are described above with reference to FIGS. 1 and 2, detailed descriptions thereof are omitted.

For example, the semiconductor chip 120 may be fixed onto the package substrate 110 via at least one process including soldering, Ag sintering, and diffusion soldering, as described above. Furthermore, as described above with reference to FIG. 3, the bump 250 may be formed on the top surface of the semiconductor chip 120.

Referring to FIG. 9, the first encapsulating material 170 and a conductive film 165 are formed on the semiconductor chip 120. To this end, a semi-hardened (e.g., B-stage) first encapsulating material 170 of which the top surface is coated with the conductive film 165 may be laminated on the package substrate 110. The lamination may be performed using a resin-coated Cu foil (RCC). The lamination using an RCC may replace an under-fill process to the semiconductor chip 120.

Referring to FIG. 10, to form the first via contact 140 and the second via contact 150, the conductive film 165 and the first encapsulating material 170 are partially removed. In detail, by partially removing the conductive film 165 and the first encapsulating material 170, a first opening 145 exposing the top surface of the shim 200 and a second opening 155 exposing the top surface of the bump 250 may be formed. The first and second openings 145 and 155 may be formed by laser drilling. As described above, when the first and second openings 145 and 155 for forming the first via contact 140 and the second via contact 150 are formed by laser drilling, the bump 250 arranged on the semiconductor chip 120 may prevent damage to the semiconductor chip 120 by the laser-drilling.

Referring to FIG. 11, the first via contact 140 and the second via contact 150 are formed by filling the first opening 145 and the second opening 155 with metals, respectively. For example, a plating process may be performed to fill the first opening 145 and the second opening 155 with metals. As described above, a balanced plating process may be performed by forming the first opening 145 on the semiconductor chip 120 (or the bump 250) and forming the second opening 155 on the shim 200 that is formed to have the same height as the semiconductor chip 120 (or the bump 250).

Referring to FIG. 12, the metal wiring 160 interconnecting the first via contact 140 and the second via contact 150 is formed by patterning the conductive film 165. The conductive film 165 may be patterned via a lithography process. Next, the external terminal 180 is connected to the package substrate 110, as shown in FIG. 13, and the second encapsulating material 190 encapsulates the package substrate 110, the first encapsulating material 170, the metal wiring 160, and a portion of the external terminal 180, as shown in FIG. 14. As a result, a semiconductor package is fabricated.

A semiconductor package fabricated by using the method of fabricating a semiconductor package, according to an embodiment of the present invention, has the technical advantage of a simplified fabrication process as compared to the related arts (e.g., stacking a redistribution substrate on the semiconductor chip 120 instead of bonding wires).

In detail, in the related art, it is necessary to perform an under-filling process on the semiconductor chip 120 before a redistribution substrate is to be stacked. However, in the method of fabricating a semiconductor substrate, according to the present invention, the processes for forming the first encapsulating material 170 and the conductive film 165 (e.g., a lamination using an RCC) may replace such an under-filling process, and thus, it is not necessary to perform an under-filling process on the semiconductor chip 120. Therefore, since an under-filling process performed on the semiconductor chip 120 may be omitted, the whole method of fabricating a semiconductor package may be simplified.

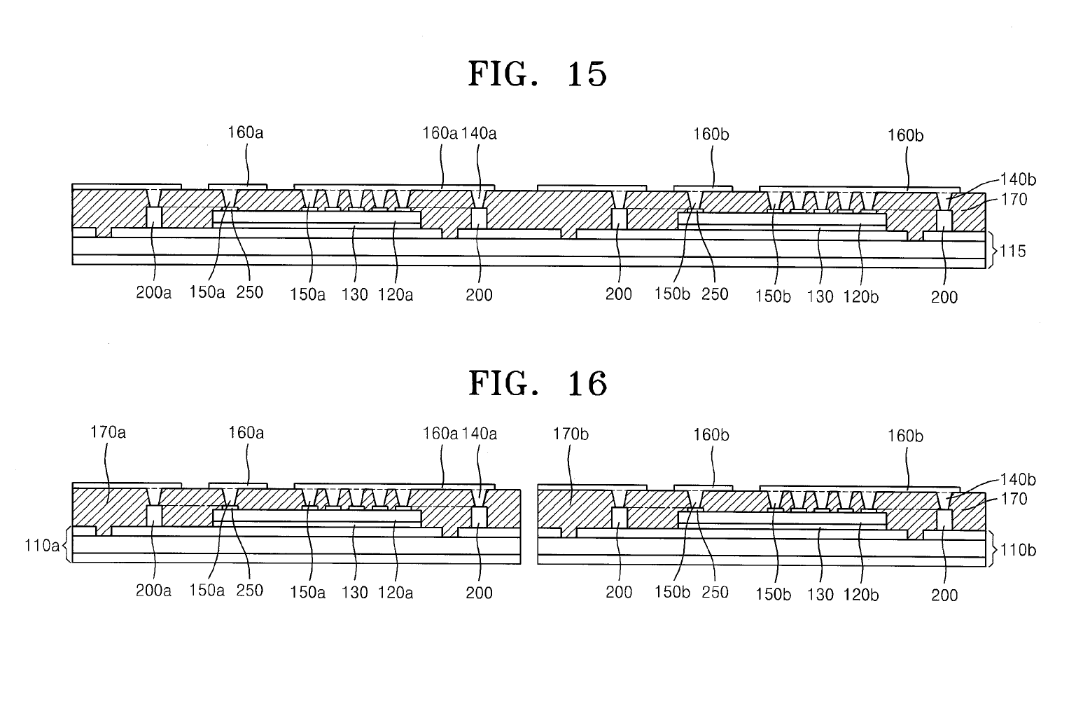

FIGS. 15 and 16 are schematic sectional views showing methods of fabricating semiconductor packages, according to other embodiments of the present invention. The methods shown in FIGS. 15 and 16 may be modifications of the method of fabricating a semiconductor package shown in FIGS. 8 through 14. Therefore, repeated descriptions of the same operations are omitted.

According to the methods shown in FIGS. 15 and 16, a plurality of semiconductor packages may be simultaneously formed by using a master card on which a plurality of package substrates arranged in a stripe shape or a matrix shape are connected to each other. For example, a first semiconductor chip and a second semiconductor chip are fixed on a master card, and a first encapsulating material and a conductive film are formed on the master card, the first semiconductor chip, and the second semiconductor chip (refer to FIGS. 8 and 9).

Next, a first via contact that connects to the master card, a second via contact that connects to the first semiconductor chip, a third via contact that connects to the master card, and a fourth via contact that connects to the second semiconductor chip are formed by partially removing the conductive film and the first encapsulating material (refer to FIGS. 10 and 11). Next, a first metal wiring interconnecting the first via contact and the second via contact and a second metal wiring interconnecting the third via contact and the fourth via contact are formed by patterning the conductive film (refer to FIG. 12).

FIG. 15 shows that first through fourth via contacts 140a, 150a, 140b, and 150b, the first metal wiring 160a, and the second metal wiring 160b are formed on a master card 115, the first semiconductor chip 120a, and the second semiconductor chip 120b. Next, as shown in FIG. 16, via a singulation process, such as a laser-cutting process, the master card 115 is split into a first package substrate 110a and a second package substrate 110b. Therefore, the first semiconductor chip 120a, the first via contact 140a, the second via contact 150a, a first portion 170a of the first encapsulating material 170, and the first metal wiring 160a are arranged on the first package substrate 110a, whereas the second semiconductor chip 120b, the third via contact 140b, the fourth via contact 150b, a second portion 170b of the first encapsulating material 170, and the second metal wiring 160b are arranged on the second package substrate 110b.

Next, the first package substrate 110a is connected to an external terminal, and the first package substrate 110a and the first portion 170a of the first encapsulating material 170 are encapsulated with a second encapsulating material. Therefore, a first semiconductor package may be fabricated. Furthermore, the second package substrate 110b is connected to an external terminal, and the second package substrate 110b and the second portion 170b of the first encapsulating material 170 are encapsulated with a second encapsulating material. Therefore, a second semiconductor package may be fabricated (refer to FIGS. 13 and 14).

According to a method of fabricating a semiconductor package, according to an embodiment of the present invention, a plurality of semiconductor packages may be mass-produced by using a master card. Therefore, a productivity of semiconductor packages may be improved.

In a semiconductor package according to an embodiment of the present invention, a semiconductor chip is connected to a package substrate via a via contact, a metal wiring, and a via contact, and thus, problems of defects due to a bonding wire process in the related art may be resolved. For example, the resistance of a current path may be reduced either by increasing the thickness of via contacts or by increasing the number of via contacts, and thus, power loss may be reduced. Furthermore, since a semiconductor chip is connected to a package substrate via a short metal wiring, inductance may also be reduced.

Furthermore, in the method of fabricating a semiconductor substrate, according to the present invention, the processes for forming a first encapsulating material and a conductive film (e.g., a lamination using an RCC) may replace such an under-filling process, and thus, it is not necessary to perform an under-filling process on a semiconductor chip. Therefore, since an under-filling process performed on the semiconductor chip is omitted, the whole method of fabricating a semiconductor package may be simplified.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a package substrate;
a semiconductor chip on the package substrate;
a first via contact coupled to the package substrate;
a second via contact coupled to the semiconductor chip;
a metal wiring that is coupled to the first via contact and the second via contact and interconnects the first via contact and the second via contact;
a first encapsulating material that is between the metal wiring and the package substrate and encapsulates the semiconductor chip; and
a second encapsulating material that encapsulates the first encapsulating material and the metal wiring.

2. The semiconductor package of claim 1, further comprising a shim arranged between the first via contact and the package substrate.

3. The semiconductor package of claim 2, wherein the cross-section of the first via contact has a reverse-trapezoidal shape, and
the cross-section of the shim has a rectangular shape.

4. The semiconductor package of claim 3, wherein the first via contact contacts the shim.

5. The semiconductor package of claim 2, further comprising a bump arranged between the semiconductor chip and the second via contact.

6. The semiconductor package of claim 5, wherein a top surface of the shim is aligned with a top surface of the bump.

7. The semiconductor package of claim 1, wherein the semiconductor chip comprises:
a pad;
a passivation film covering a top surface of the semiconductor chip to expose at least a portion of the pad; and
a bump which contacts the portion of the pad exposed by the passivation film.

8. The semiconductor package of claim 7, wherein the second via contact contacts the bump.

9. The semiconductor package of claim 1, wherein a bottom surface of the metal wiring contacts the first encapsulating material, and
a top surface of the metal wiring contacts the second encapsulating material.

10. A method of fabricating a semiconductor package, the method comprising:
fixing a semiconductor chip onto a package substrate;
laminating a semi-hardened first encapsulating material onto the package substrate and the semiconductor chip, a top surface of the first encapsulating material being coated with a conductive film;
forming a first via contact that connects to the package substrate and a second via contact that connects to the semiconductor chip by partially removing the conductive film and the first encapsulating material;
forming a metal wiring interconnecting the first via contact and the second via contact by patterning the conductive film; and
encapsulating the first encapsulating material and the metal wiring with a second encapsulating material.

11. The method of claim 10, wherein laminating the semi-hardened first encapsulating material onto the package substrate and the semiconductor chip is performed using a resin-coated copper foil (RCC).

12. The method of claim 10, further comprising, before laminating the semi-hardened first encapsulation material onto the package substrate and the semiconductor chip, fixing a shim to the package substrate.

13. The method of claim 12, wherein the semiconductor chip comprises a pad and a bump arranged on the pad, and a top surface of the shim is aligned with a top surface of the bump.

14. The method of claim 13, wherein forming the first via contact and the second via contact comprises:
forming a first opening exposing the top surface of the shim and a first opening exposing the top surface of the bump by partially removing the conductive film and the first encapsulating material; and
forming the first via contact and the second via contact by filling the first opening and the second opening with metals.

15. The method of claim 14, wherein the first opening and the second opening are formed using laser-drilling.

16. The method of claim 10, wherein the semiconductor chip is fixed onto the package substrate via at least one process including soldering, silver (Ag) sintering, and diffusion soldering.

17. A method of forming a semiconductor package, the method comprising:
fixing a first semiconductor chip and a second semiconductor chip onto a master card;
forming a first encapsulating material and a conductive film on the master card, the first semiconductor chip, and the second semiconductor chip;
forming a first via contact that connects to the master card, a second via contact that connects to the first semiconductor chip, a third via contact that connects to the master card, and a fourth via contact that connects to the second semiconductor chip by partially removing the conductive film and the first encapsulating material;
forming a first metal wiring interconnecting the first via contact and the second via contact and a second metal wiring interconnecting the third via contact and the fourth via contact by patterning the conductive film; and
splitting the master card into a first package substrate and a second package substrate.

18. The method of claim 17, wherein the forming of the first encapsulating material and the conductive film comprises laminating the semi-hardened first encapsulating material of which a top surface is coated with the conductive film onto the master card, the first semiconductor chip, and the second semiconductor chip.

19. The method of claim 18, wherein the first semiconductor chip, the first via contact, the second via contact, a first portion of the first encapsulating material, and the first metal wiring are arranged on the first package substrate, and
the second semiconductor chip, the second via contact, the second via contact, a second portion of the first encapsulating material, and the second metal wiring are arranged on the second package substrate.

20. The method of claim 19, further comprising encapsulating the first portion of the first encapsulating material with a second encapsulating material.

21. The method of claim 20, further comprising, before the encapsulating of the first portion of the first encapsulating material with the second encapsulating material, connecting the first package substrate to an external terminal.
